(19) United States
(12) Patent Application Publication
(10) Pub. No.: US 2009/0230541 A1
(43) Pub. Date: Sep. 17, 2009

(54) SEMICONDUCTOR DEVICE AND MANUFACTURING METHOD OF THE SAME

(75) Inventors: Makoto Araki, Tokyo (JP); Shimpei Ishida, Tokyo (JP); Shigeru Nakamura, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/395,008

(22) Filed: Feb. 27, 2009

(30) Foreign Application Priority Data
Mar. 13, 2008 (JP) 2008-064322

(51) Int. Cl. H01L 23/48; H01L 21/78; H01L 21/50

(52) U.S. Cl. 257/693; 438/113; 257/E23.011; 257/E21.599; 257/E21.499

(57) ABSTRACT

A semiconductor device in which a chip is embedded in a wiring board and bump electrodes formed over the front surface of the semiconductor chip are flip-chip coupled to wiring formed in the wiring board and the entire back surface of the semiconductor chip functions well as a back electrode and a method of manufacturing the semiconductor device. A semiconductor chip is embedded inside a wiring board. The semiconductor chip is flip-chip coupled (face down) to a base substrate as the core layer of the wiring board through bump electrodes. A conductive film is formed over the semiconductor chip's surface reverse to the surface over which bump electrodes are formed. The conductive film functions as a back electrode which supplies a reference voltage to the integrated circuit in the semiconductor chip. The conductive film is electrically coupled to third-layer wiring through vias.

### CROSS-REFERENCE TO RELATED APPLICATIONS

The disclosure of Japanese Patent Application No. 2008-64322 filed on Mar. 13, 2008 including the specification, drawings and abstract is incorporated herein by reference in its entirety.

### BACKGROUND OF THE INVENTION

The present invention relates to a semiconductor device and a manufacturing method of the same and more particularly to a technique which is useful for the manufacture of a package with a semiconductor chip embedded in a wiring board.

Japanese Unexamined Patent Publication No. 2005-228901 describes a technique which reduces the size of a semiconductor device by embedding a semiconductor chip in a wiring board. In this technique, the semiconductor chip is electrically coupled to wiring in the wiring board through bump electrodes formed over the chip.

Japanese Unexamined Patent Publication No. 2005-223223 describes a semiconductor device which radiates heat efficiently and decreases the impedance of the power supply wiring effectively. Concretely a semiconductor chip is embedded in a wiring board. The semiconductor chip embedded in the wiring board is coupled to wiring of the wiring board through bump electrodes formed over the front surface of the semiconductor chip. The back side of the semiconductor chip lies over a ground layer (ground wiring) formed in the wiring board.

### SUMMARY OF THE INVENTION

In recent years, the use of mobile communication devices which typically use communication methods such as GSM (Global System for Mobile Communications), PCS (Personal Communication Systems), PDC (Personal Digital Cellular) and CDMA (Code Division Multiple Access) has been spreading around the world. Generally this kind of mobile communication device includes a baseband circuit having a function to control transmission and reception of signals, an RF (radio frequency) IC having a function to modulate and demodulate signals, and a power amplifier for amplifying input electric power into an output power level required for telephone conversation.

The baseband circuit, RFIC and power amplifier are formed over different semiconductor chips. For example, a semiconductor chip where a baseband circuit is formed is called a baseband IC chip, and a semiconductor chip where an RFIC is formed is called an RFIC chip. A semiconductor chip where a power amplifier is formed is called a power amplifier IC chip. The baseband IC chip, RFIC chip, and power amplifier IC chip are commercially available in the form of packages.

Recently there has been a growing tendency for mobile phones to use higher frequency bands. In dealing with high-frequency band signals, adequate measures against noise must be taken. For noise reduction, stable supply of a reference voltage (GND) is necessary. For stable supply of a reference voltage, reduction of the impedance of reference wiring which carries the reference voltage is effective. For this reason, a reference voltage supply method which reduces the impedance of reference wiring has been adopted.

FIG. 42 shows an example of a packaged semiconductor chip. The package illustrated in FIG. 42 is a BGA (Ball Grid Array). BGA refers to a kind of IC package where external connection electrodes from the package in the form of metal balls such as solder balls are arranged in a grid pattern on the back of a wiring board (surface reverse to the surface on which a chip is mounted), or a kind of surface mount package. More specifically, as shown in FIG. 42, wiring 101 and a solid pattern 102 larger than the wiring 101 are formed over the front surface of a wiring substrate 100 (chip-mounting surface). The wiring 101 and solid pattern 102 are coupled to solder balls (external connection terminals) 104 formed over the back surface of the wiring substrate 100 through conductive vias 103 penetrating the wiring substrate 100. A semiconductor chip 106 is bonded to the solid pattern 102 formed over the front surface of the wiring substrate 100 using conductive paste 105. This semiconductor chip 106 is mounted over the wiring substrate 100 with its back surface in contact with the conductive paste 105. On the other hand, a pad (not shown) is formed over the front surface of the semiconductor chip 106 and the pad is electrically coupled to the wiring 101 formed over the wiring substrate 100 through wires 107. The chip-mounting surface of the wiring substrate 100 is sealed with resin 108.

In the BGA thus configured, the entire back surface of the semiconductor chip 106 is coupled to the solid pattern 102 through the conductive paste 105. The back surface of the semiconductor chip 106 functions as a back electrode which supplies a reference voltage to the integrated circuit inside the semiconductor chip 106 and this back electrode is electrically coupled to the large solid pattern 102. In other words, in the BGA, the back electrode formed over the back surface of the semiconductor chip 106 is coupled to the solder balls 104 as external connection terminals through the solid pattern 102 formed over the front surface of the wiring substrate 100. Since the solid pattern 102 is large, its impedance (resistance) is low. Hence, since the back electrode of the semiconductor chip 106 which supplies a reference voltage is coupled to the solid pattern 102 with a low impedance, it can stably supply a reference voltage to the inside of the semiconductor chip 106 even if the semiconductor chip 106 uses high-frequency signals. In short, in the BGA shown in FIG. 42, noise is reduced in the supply of a reference voltage.

FIG. 43 shows another example of a packaged semiconductor chip. As illustrated in FIG. 43, the package uses a lead frame. More specifically, as shown in FIG. 43, a semiconductor chip 106 is mounted over a tab 109 of a conductive material through conductive paste 105. A pad (not shown) formed over the front surface of the semiconductor chip 106 is coupled to a lead 110 through wires 107. The semiconductor chip 106 is sealed with resin 108.

In this structure as well, the entire back surface of the semiconductor chip 106 is coupled to the tab 109 through the conductive paste 105. The back surface of the semiconductor chip 106 functions as a back electrode which supplies a reference voltage to the integrated circuit inside the semiconductor chip 106 and this back electrode is electrically coupled to the large tab 109. Hence, since the back electrode of the semiconductor chip 106 which supplies a reference voltage is coupled to the tab 109 with a low impedance, it can stably supply a reference voltage to the inside of the semiconductor chip 106 even if the semiconductor chip 106 uses high-frequency signals. In short, in the package shown in FIG. 43 as well, noise is reduced in the supply of a reference voltage.

As described above, the packages shown in FIGS. 42 and 43 offer an advantage that the use of the entire back surface of the semiconductor chip 106 as a back electrode assures stable supply of a reference voltage with less noise. However, the structures shown in FIGS. 42 and 43 have the following problem. The pad formed over the front surface of the semiconductor chip 106 is coupled to the wiring 101 (or lead 110) through the wires 107. The pad formed over the front surface of the semiconductor chip 106 is used to supply signals and power supply voltages. This means that high-frequency signals are transmitted through the wires 107 to the pad and wiring 101 (or lead 110) coupled through the wires 107. When the wires 107 are used to transmit high-frequency signals, a serious deterioration in electrical properties such as signal delays or impedance rise may occur. In other words, the packages shown in FIGS. 42 and 43 may cause a problem such as signal delays or impedance rise.

A possible solution to this problem is to avoid the use of wires for coupling of the semiconductor chip and wiring substrate. FIG. 44 shows that a semiconductor chip is coupled to a wiring substrate by the flip-chip coupling method. As shown in FIG. 44, bump electrodes 106a formed over the front surface of the semiconductor chip 106 are used to couple the chip to wiring 101 of a wiring substrate 100. Since this flip-chip coupling method allows the semiconductor chip 106 to be coupled to the wiring 101 without using wires, an electrical deterioration due to the use of wires such as signal delays or impedance rise can be prevented even if high frequency signals are used. However, in the conventional flip-chip coupling method as illustrated in FIG. 44, the entire back surface of the semiconductor chip 106 is not used as a back electrode and it is difficult to assure stable supply of a reference voltage with less noise. In short, the problem to be solved in flip-chip coupling is to assure stable supply of a reference voltage. Particularly it is important to supply a reference voltage stably with less noise in flip-chip coupling of a semiconductor chip which deals with high-frequency signals.

Another demand in semiconductor chip packaging is package size reduction. For example, there is a demand for smaller or thinner mobile phones. As stated earlier, mobile phones require a plurality of semiconductor chips including a baseband IC chip, an RFIC chip and a power amplifier IC chip. If these semiconductor chips are packaged separately, it is impossible to realize a small mobile phone as desired. For this reason, techniques that plural semiconductor chips are mounted over a single wiring board and packaged together have been studied. When plural semiconductor chips are packaged into a package, the device size can be smaller than when they are separately packaged.

As another approach to reducing the package size, some chips among plural semiconductor chips are embedded in the wiring board (embedded package). For example, Japanese Unexamined Patent Publication No. 2005-228901 discloses a structure that some semiconductor chips are embedded in a wiring board. When some semiconductor chips among plural semiconductor chips are embedded in the wiring board, the number of semiconductor chips mounted over the front surface of the wiring board is decreased and thus the package size can be smaller. However, according to Japanese Unexamined Patent Publication No. 2005-228901, a semiconductor chip embedded in the wiring board is coupled to wires formed in the wiring board through bump electrodes by the flip-chip coupling method. In this case, the back surface of the semiconductor chip is not used as a back electrode. In the technique described in Japanese Unexamined Patent Publication No. 2005-228901, since the entire back surface of the semiconductor chip is not used as a back electrode, it may be considered that this structure does not assure stable supply of a reference voltage with less noise. Therefore, when a semiconductor chip embedded in the wiring board deals with high-frequency signals, it is thought that the problem of noise may occur due to reference voltage fluctuations, resulting to a serious deterioration in semiconductor chip electrical properties.

Another approach is described in Japanese Unexamined Patent Publication No. 2005-223223. In the technique disclosed in this patent document, a semiconductor chip is embedded in a wiring board and the embedded chip is coupled to wiring formed in the wiring board by the flip-chip coupling method. The back surface of the semiconductor chip is coupled to a ground layer formed inside the wiring board. In other words, ideally this technique should assure stable supply of a reference voltage with less noise because the entire back surface of the flip-chip coupled semiconductor chip, as a back electrode, is coupled to the ground layer.

However, the technique is less likely to work “ideally” because it seems difficult that the technique assures a good contact between the entire back surface of the semiconductor chip and the ground layer. The reason is as follows. In the manufacturing method described in the document, the wiring board with a semiconductor chip embedded therein is manufactured by pressing a first original substrate with a flip-chip coupled semiconductor chip and a second original substrate with a ground layer formed therein through a prepreg (see FIGS. 14 and 15 in Japanese Unexamined Patent Publication No. 2005-223223). In this manufacturing technique, the prepreg between the semiconductor chip back surface and the ground layer should be pushed out of the semiconductor chip under pressure and the semiconductor chip back surface and the ground layer are brought into close contact with each other. However, in this manufacturing method, some prepreg may remain between the semiconductor chip and the ground layer, causing a poor electrical contact between the semiconductor chip back surface and the ground layer. Thus if the electrical contact between the entire back surface of the semiconductor chip and the ground layer is not satisfactory, it would be impossible to assure stable supply of a reference voltage with less noise. Besides, even if the prepreg between the semiconductor chip and the ground layer is removed, a problem may occur from the viewpoint of adhesion between the semiconductor chip and the ground layer. According to the technique described in the document, although the semiconductor chip should directly contact the ground layer, peeling may occur between the semiconductor chip and the ground layer. Concretely, the semiconductor chip is made of silicon and the ground layer is a copper film. Since silicon and copper do not contact each other so well, peeling easily occurs. Particularly when the entire back surface of the semiconductor chip contacts the ground layer, the area of contact between silicon and copper is relatively large and peeling more easily occurs. It is thought that if peeling occurs between the back surface of the semiconductor chip and the ground layer, the electrical contact between the entire back surface of the semiconductor chip and the ground layer becomes inadequate and it becomes impossible to supply a reference voltage stably with less noise.

An object of the present invention is to provide a semiconductor device in which the entire back surface of a semiconductor chip functions well as a back electrode when the chip is embedded in a wiring board and bump electrodes formed over the front surface of the semiconductor chip are flip-chip coupled to wiring formed in the wiring board, and also provide a method of manufacturing the same.

The above and further objects and novel features of the invention will more fully appear from the following detailed description in this specification and the accompanying drawings.

Preferred embodiments of the invention which will be disclosed herein are briefly outlined below.

According to a preferred embodiment of the present invention, a semiconductor device comprises (a) a rectangular first semiconductor chip and (b) a wiring board in which the first semiconductor chip is embedded. The first semiconductor chip includes (a1) bump electrodes formed over the first semiconductor chip's first surface and (a2) a conductive film which is formed over a second surface reverse to the first surface of the first semiconductor chip and functions as a back electrode. The wiring board includes (b1) a core layer coupled to the first semiconductor chip through the bump electrodes formed over the first surface of the first semiconductor chip and (b2) an insulating layer formed over the core layer's chip-mounting surface so as to cover the first semiconductor chip. The wiring board further includes (b3) an opening which extends from the insulating layer and reaches the conductive film formed over the second surface of the first semiconductor chip, (b4) a conductive via which fills the opening, and (b5) wiring coupled to the via. The conductive film formed over the second surface of the first semiconductor chip is electrically coupled to the wiring formed in the wiring board through the via.

In the semiconductor device according to this preferred embodiment, since the conductive film is formed over the back surface of the semiconductor chip and the conductive film is coupled to the wiring of the wiring board, the entire back surface of the semiconductor chip can function well as a back electrode.

According to a preferred embodiment of the present invention, a method of manufacturing a semiconductor device includes the steps of (a) forming an integrated circuit over a first surface of a semiconductor wafer, (b) after the step (a), forming a first conductive film over a second surface reverse to the first surface of the semiconductor wafer, and (c) after the step (b), dicing the semiconductor wafer into separate semiconductor chips. After the step (c) is the step (d) of forming bump electrodes over the first surface of the semiconductor chip; after the step (d) is the step (e) of mounting the semiconductor chip over a base substrate as a core layer of a wiring board through the bump electrodes; and after the step (e) is the step (f) of forming, over the base substrate's chip-mounting surface, an insulating layer covering the semiconductor chip. After the step (f) is the step (g) of making an opening which extends from the insulating layer and reaches the first conductive film formed over the second surface of the semiconductor chip; and after the step (g) is the step (h) of forming a second conductive film over the insulating layer including the opening to fill the second conductive film in the opening to make a via. After the step (h) is the step (i) of patterning the second conductive film formed over the insulating layer and the via to form wiring. The first conductive film formed over the second surface of the semiconductor chip and the wiring formed over the insulating layer are electrically coupled through the via.

In the method of manufacturing a semiconductor device according to this preferred embodiment, since the conductive film is formed over the back surface of the semiconductor chip and the conductive film is coupled to the wiring of the wiring board, the entire back surface of the semiconductor chip can function well as a back electrode.

The advantageous effects brought about by the preferred embodiments of the present invention disclosed herein are briefly described below.

According to the preferred embodiments, since the conductive film is formed over the back surface of the semiconductor chip and the conductive film is coupled to the wiring of the wiring board, the entire back surface of the semiconductor chip can function well as a back electrode.

### BRIEF DESCRIPTION OF THE DRAWINGS

FIG. 1 is a block diagram showing the structure of a mobile phone;

FIG. 2 is a sectional view of a semiconductor device according to a first embodiment of the present invention;

FIG. 3 illustrates a step of the semiconductor device manufacturing process according to the first embodiment;

FIG. 4 is a flowchart showing semiconductor device manufacturing steps after the step shown in FIG. 3;

FIG. 5 is a sectional view showing a semiconductor device manufacturing step after the step shown in FIG. 4;

FIG. 6 is a plan view showing the semiconductor device manufacturing step shown in FIG. 5;

FIG. 7 is a sectional view showing a semiconductor device manufacturing step after the step shown in FIG. 5;

FIG. 8 is a sectional view showing a semiconductor device manufacturing step after the step shown in FIG. 7;

FIG. 9 is a sectional view showing a semiconductor device manufacturing step after the step shown in FIG. 8;

FIG. 10 is a sectional view showing a semiconductor device manufacturing step after the step shown in FIG. 9;

FIG. 11 is a sectional view showing a semiconductor device manufacturing step after the step shown in FIG. 10;

FIG. 12 is a plan view showing the semiconductor device manufacturing step shown in FIG. 11;

FIG. 13 is a sectional view showing a semiconductor device manufacturing step after the step shown in FIG. 11;

FIG. 14 is a sectional view showing a semiconductor device manufacturing step after the step shown in FIG. 13;

FIG. 15 is a sectional view showing a semiconductor device manufacturing step after the step shown in FIG. 14;

FIG. 16 is a sectional view showing a semiconductor device manufacturing step after the step shown in FIG. 15;

FIG. 17 is a sectional view showing a semiconductor device manufacturing step after the step shown in FIG. 16;

FIG. 18 is a sectional view showing the structure of a semiconductor device according to a second embodiment of the present invention;

FIG. 19 is a sectional view showing a semiconductor device manufacturing step according to the second embodiment;

FIG. 20 is a sectional view showing a semiconductor device manufacturing step after the step shown in FIG. 19;

FIG. 21 is a sectional view showing a semiconductor device manufacturing step after the step shown in FIG. 20;

FIG. 22 is a sectional view showing a semiconductor device manufacturing step after the step shown in FIG. 21;

FIG. 23 is a sectional view showing a semiconductor device manufacturing step after the step shown in FIG. 22;

FIG. 24 is a sectional view showing a semiconductor device manufacturing step after the step shown in FIG. 23;

FIG. 25 is a plan view showing the semiconductor device manufacturing step shown in FIG. 24;

FIG. 26 is a sectional view showing a semiconductor device manufacturing step after the step shown in FIG. 24;

FIG. 27 is a sectional view showing a semiconductor device manufacturing step after the step shown in FIG. 26;

FIG. 28 is a sectional view showing a semiconductor device manufacturing step after the step shown in FIG. 27;

FIG. 29 is a sectional view showing a semiconductor device manufacturing step after the step shown in FIG. 28;

FIG. 30 is a sectional view showing a semiconductor device manufacturing step after the step shown in FIG. 29;

FIG. 31 is a sectional view showing the structure of a semiconductor device according to a third embodiment of the present invention;

FIG. 32 is a sectional view of a semiconductor device manufacturing step according to the third embodiment;

FIG. 33 is a sectional view showing a semiconductor device manufacturing step after the step shown in FIG. 32;

FIG. 34 is a sectional view showing a semiconductor device manufacturing step after the step shown in FIG. 33;

FIG. 35 is a sectional view showing a semiconductor device manufacturing step after the step shown in FIG. 34;

FIG. 36 is a plan view showing the semiconductor device manufacturing step shown in FIG. 35;

FIG. 37 is a sectional view showing a semiconductor device manufacturing step after the step shown in FIG. 35;

FIG. 38 is a sectional view showing a semiconductor device manufacturing step after the step shown in FIG. 37;

FIG. 39 is a sectional view showing a semiconductor device manufacturing step after the step shown in FIG. 38;

FIG. 40 is a sectional view showing a semiconductor device manufacturing step after the step shown in FIG. 39;

FIG. 41 is a sectional view showing a semiconductor device manufacturing step after the step shown in FIG. 40;

FIG. 42 is a sectional view of a semiconductor device which the present inventors have examined;

FIG. 43 is a sectional view of a semiconductor device which the present inventors have examined; and

FIG. 44 is a sectional view of a semiconductor device which the present inventors have examined.

### DETAILED DESCRIPTION OF THE PREFERRED EMBODIMENTS

The preferred embodiments below will be described separately as necessary, but such descriptions are not irrelevant to each other unless otherwise specified. They are, in whole or in part, variations of each other and sometimes one description is a detailed or supplementary form of another.

Also, in the preferred embodiments described below, even when the numerical datum for an element (the number of pieces, numerical value, quantity, range, etc.) is indicated by a specific numerical value, it is not limited to the indicated specific numerical value unless otherwise specified or theoretically limited to the specific numerical value; it may be larger or smaller than the specific numerical value.

In the preferred embodiments described below, it is needles to say that their constituent elements (including constituent steps) are not necessarily essential unless otherwise specified or considered theoretically essential.

Likewise, in the preferred embodiments described below, when a specific form or positional relation is indicated for an element, it should be interpreted to include forms or positional relations which are virtually equivalent or similar to the specific one unless otherwise specified or unless the specific one is considered theoretically necessary. The same can be said of numerical values or ranges as mentioned above.

In all the drawings that illustrate the preferred embodiments, elements with like functions are basically designated by like reference numerals and repeated descriptions thereof are omitted. For easy understanding, hatching may be used even in a plan view.

### First Embodiment

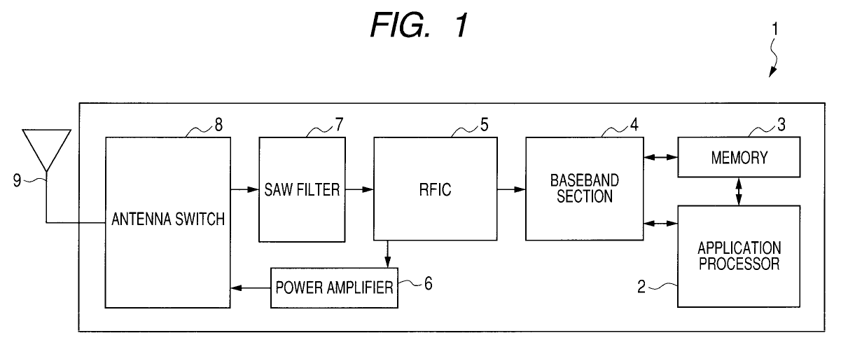

FIG. 1 is a block diagram showing the configuration of a transceiver module of a mobile phone. As shown in FIG. 1, the mobile phone 1 includes an application processor 2, a memory 3, a baseband section 4, an RFIC 5, a power amplifier 6, a SAW (Surface Acoustic Wave) filter 7, an antenna switch 8, and an antenna 9.

The application processor 2, for example, comprised of a CPU (Central Processing Unit), performs the application function of the mobile phone 1. Concretely, it reads a command from the memory 3, decodes it and makes various calculations and control operations according to the result of decoding to perform the application function. The memory 3 has a function to store data and, for example, it stores a program to run the application processor 2 and data which has been processed by the application processor 2. Also the memory 3 can access the baseband section 4 and store data which has been processed by the baseband section.

The baseband section 4 incorporates a CPU as a central controller. To transmit a signal, it digitalizes a voice signal (analog signal) from a user (caller) to generate a baseband signal. To receive a signal, it generates a voice signal from a baseband signal as a digital signal.

In transmitting a signal, the RFIC 5 modulates a baseband signal to generate a radio frequency signal and in receiving a signal, it demodulates the received signal and generates a baseband signal. The power amplifier 6 is a circuit which newly generates and outputs a large power signal similar to a weak input signal using the power supplied from a power source. The SAW filter 7 allows passage of signals only in a prescribed frequency band among received signals.

The antenna switch 8 separates input signals which the mobile phone 1 receives and output signals which it sends, and the antenna 9 sends and receives electric waves.

Next, how the mobile phone 1, configured as mentioned above, operates will be briefly explained. First, how it operates to transmit a signal is explained below. The baseband signal generated by the baseband section 4 by converting an analog signal into a digital signal, enters the RFIC 5. The RFIC 5 converts the received baseband signal into an intermediate frequency signal. The intermediate frequency signal is converted into a radio frequency signal by a modulating signal source and a mixer. The radio frequency signal as a result of conversion is sent from the RFIC 5 to the power amplifier (RF module) 6. The radio frequency signal which has entered the power amplifier 6 is amplified by the power amplifier 6 and sent through the antenna switch 8 to the antenna 9.

Next, how a signal is received is explained. A radio frequency signal received by the antenna 9 (received signal) passes through the SAW filter 7, and then enters the RFIC 5. In the RFIC 5, the received signal is amplified and then converted into an intermediate frequency signal by a modulating signal source and a mixer. The intermediate frequency signal is detected to extract a baseband signal. Then, the baseband signal is sent from the RFIC 5 to the baseband section 4. The baseband signal is processed in the baseband section 4 so that a voice signal is generated.

As described above, the mobile phone uses the baseband section 4, RFIC 5, and power amplifier 6 to perform the signal transmission and reception function as a mobile phone. In this mobile phone, the baseband section 4, RFIC 5, and power amplifier 6 are comprised of a baseband IC chip, an RFIC chip, and a power amplifier IC chip, respectively. The baseband IC chip, RFIC chip, and power amplifier IC chip may be separately packaged into individual packages. However, in order to reduce the mobile phone size, techniques of packaging the baseband IC chip, RFIC chip, and power amplifier IC chip into one package have been studied. In other words, techniques of mounting the baseband IC chip, RFIC chip and power amplifier IC chip over a single wiring board have been pursued. In recent years, however, there has been a demand for further compact mobile phones. For this reason, techniques of embedding some semiconductor chips in the wiring board have been explored in order to make the chip-mounting area smaller than when three semiconductor chips are mounted over the front surface of a single wiring board as described above. When some semiconductor chips are embedded in the wiring board, the number of semiconductor chips mounted over the front surface of the wiring board is decreased. This means that the package can be smaller. This first embodiment concerns a package in which some semiconductor chips among a plurality of semiconductor chip are embedded in the wiring board.

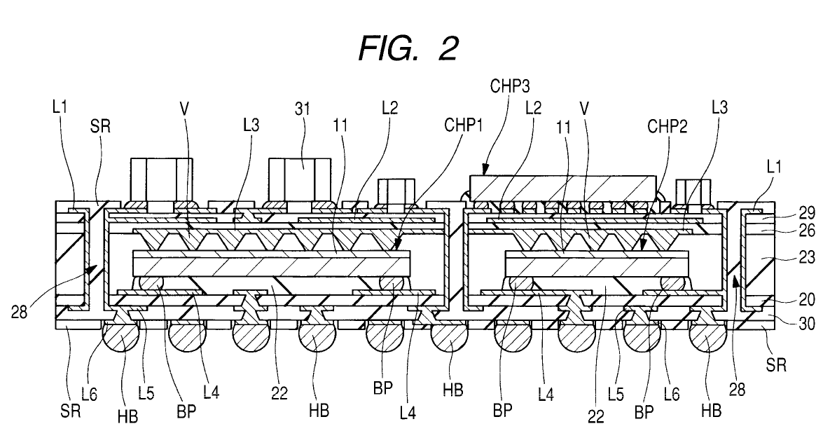

FIG. 2 is a sectional view of a package (semiconductor device) according to the first embodiment. As illustrated in FIG. 2, in the package according to the first embodiment, two semiconductor chips are embedded in the wiring board and another semiconductor chip is mounted over the front surface of the wiring board. Referring to FIG. 2, the structure of the package in the first embodiment will be described concretely next.

As shown in FIG. 2, fourth-layer wiring L4 is formed over the upper surface of a base substrate 20 as the core layer of the wiring board and fifth-layer wiring L5 is formed over the reverse or lower surface of the base substrate 20. A semiconductor chip CHP1 and a semiconductor chip CHP2 are mounted over the base substrate 20. The semiconductor chip CHP1 is electrically coupled to the fourth-layer wiring L4 formed over the base substrate 20 through bump electrodes BP. Similarly the semiconductor chip CHP2 is electrically coupled to the fourth-layer wiring L4 formed over the base substrate 20 through bump electrodes BP. Paste 22 is filled between the semiconductor chip CHP1 and the base substrate 20 and between the semiconductor chip CHP2 and the base substrate 20.

An insulating layer 23 is formed in a way to cover the semiconductor chips CHP1 and CHP2 and third-layer wiring L3 is formed over the insulating layer 23. The third-layer wiring L3 is electrically coupled to the semiconductor chips CHP1 and CHP2 through vias V made in the insulating layer 23. An insulating layer 26 is formed over the third-layer wiring L3 and second-layer wiring L2 is formed over the insulating layer 26. Furthermore, an insulating layer 29 is formed over the second-layer wiring L2 and first-layer wiring L1 is formed over the insulating layer 29.

On the other hand, an insulating layer 30 is formed under the fifth-layer wiring L5 formed over the lower surface of the base substrate 20 and sixth-layer wiring L6 is formed over the lower surface of the insulating layer 30.

Thus the wiring board is configured as follows: the first-layer wiring L1 to the sixth-layer wiring L6 form a multi-layer interconnection and the base substrate 20 serves as the core layer. The semiconductor chips CHP1 and CHP2 are embedded inside the wiring board in a way that they lie over the base substrate 20 placed inside the wiring board.

A through wiring 28 which penetrates part of the wiring board is formed in the wiring board. The through wiring 28 allows electrical coupling of the multi-layer interconnection formed in the wiring board. The first-layer wiring L1 of the wiring board is covered by solder resist SR with some part of the first-layer wiring L1 exposed from the solder resist SR. The exposed part of the first-layer wiring L1 is coupled to the semiconductor chip CHP3 and passive components 31. In other words, the semiconductor chip CHP3 and passive components 31 are mounted over the front surface of the wiring board.

Solder balls HB as external connection terminals are mounted over the sixth-layer wiring L6. These solder balls HB are surrounded by solder resist SR. The package according to the first embodiment is thus structured.

In the package according to the first embodiment, the semiconductor chips CHP1 and CHP2 are embedded in the wiring board. This offers an advantage that the package size can be smaller. If the semiconductor chips CHP1 and CHP2 are not embedded in the wiring board, the semiconductor chips CHP1 to CHP3 and passive components must be mounted over the front surface of the wiring board and the wiring board must be larger. In other words, the wiring board must be so large that the semiconductor chips CHP1 to CHP3 and passive components can be mounted over it.

On the other hand, in this embodiment, since the semiconductor chips CHP1 and CHP2 are embedded in the wiring board, only the semiconductor chip CHP3 and passive components are mounted over the surface of the wiring board. Therefore, the wiring board can be smaller than when the semiconductor chips CHP1 to CHP3 and passive components are mounted over the wiring board front surface. Consequently, the mobile phone can be smaller.

For example, the semiconductor chip CHP1 and semiconductor chip CHP2 which are embedded in the wiring board are a power amplifier IC chip and an RFIC chip as mobile phone components, respectively. The semiconductor chip CHP3 mounted over the wiring board front surface is, for example, a baseband IC chip as a mobile phone component and the passive components are, for example, a chip capacitor, a resistor, and an inductor.

Next, how the semiconductor chips CHP1 and CHP2 embedded in the wiring board are coupled to the wiring board will be explained. For example, the semiconductor chip CHP1 is mounted over the base substrate 20 as the core layer of the wiring board. The fourth-layer wiring L4 formed over the base substrate 20 and the semiconductor chip CHP1 are electrically coupled through bump electrodes BP of the semiconductor chip CHP1. Specifically, the semiconductor chip CHP1 is embedded in the wiring board and flip-chip coupled (face down) over the base substrate 20 located inside the wiring board. Likewise, the semiconductor chip CHP2 is flip-chip coupled over the base substrate 20 through bump electrodes BP. Flip-chip coupling of the semiconductor chips CHP1 and CHP2 through bump electrodes BP brings about the following advantage.

The semiconductor chip CHP1 is a power amplifier IC chip and the semiconductor chip CHP2 is an RFIC chip. The power amplifier IC chip and RFIC chip include integrated circuits which deal with high frequency signals. Hence, if the power amplifier IC chip and RFIC chip should be coupled to the wiring board through wires (face up), signal delays and impedance rise will be more likely to occur because high frequency signals pass through the wires. On the other hand, in the first embodiment, the semiconductor chip CHP1 as a power amplifier IC chip and the semiconductor chip CHP2 as an RFIC chip are flip-chip coupled through bump electrodes BP. Since wires are not used for electrical coupling between the semiconductor chip CHP1 and the wiring board or between the semiconductor chip CHP2 and the wiring board, signal delays or impedance rise due to high frequency signals passing through wires cannot occur. Thus it can be said that for semiconductor chips which deal with high frequency signals, such as the power amplifier IC chip and RFIC chip, it is more desirable to use bump electrodes to couple them to the wiring board than wires. For this reason, in the first embodiment, deterioration in high frequency electrical characteristics is prevented by flip-chip coupling the semiconductor chips CHP1 and CHP2 embedded in the wiring board to the base substrate 20.

However, when the semiconductor chip CHP 1 or CHP2 is flip-chip coupled to the base substrate 20, there is a new problem. For example, when the semiconductor chip CHP1 is flip-chip coupled to the base substrate 20 through bump electrodes BP, effective use of the surface (back) reverse to the bump electrode bearing (front) surface of the semiconductor chip CHP1 is not considered. For example, when a semiconductor chip is not embedded in a wiring board but mounted over a wiring board front surface, wires may be used to couple the semiconductor chip to the wiring board. In this case, the semiconductor chip is coupled to the wiring board face up and the back surface of the semiconductor chip is in contact with the wiring board. Therefore, the semiconductor chip's back surface in contact with the wiring board can be used as a back electrode which supplies a reference voltage. However, as mentioned above, if wires are used to couple the semiconductor chip to the wiring board, signal delays or impedance rise may occur. For this reason, in mounting a semiconductor chip over a wiring board front surface, the semiconductor chip may be flip-chip coupled to the wiring board through bump electrodes. However, in case of flip-chip coupling the semiconductor chip to the wiring board front surface through bump electrodes, the semiconductor chip's back surface (reverse to the bump electrode bearing surface) is up and not in direct contact with the wiring board. For this reason, in flip-chip coupling of a semiconductor chip to a wiring board front surface, no one has thought of using the back surface of the semiconductor chip as a back electrode. Therefore, flip-chip coupling of a semiconductor chip to a wiring board front surface prevents delays of high frequency signals and impedance rise due to wires but does not assure stable supply of a reference voltage. In other words, although a semiconductor chip which deals with high frequency signals must supply a reference voltage stably and reduce noise due to reference voltage fluctuations, if the semiconductor chip is flip-chip coupled to the wiring board front surface, its back surface is not used as a back electrode. If the entire back surface of the semiconductor chip functions as a back electrode, it is used to supply a reference voltage and because of its large area, its impedance is low and a reference voltage is stably supplied.

Taking the above circumstances into consideration, in the first embodiment, the semiconductor chips CHP1 and CHP2 embedded in the wiring board are coupled face down to the wiring board through bump electrodes BP. When the semiconductor chip CHP1 is embedded in the wiring board and coupled face down to the wiring board, the difference from the case that the semiconductor chip is mounted face down over the wiring board front surface (flip chip coupling) is that the back surface of the semiconductor chip CHP1 (reverse to the bump electrode bearing surface) is covered by the insulating layer 23 and the third-layer wiring L3 lies over the insulating layer 23. The first embodiment takes advantage of this difference to provide one feature thereof.

Next, one feature of the first embodiment will be described. In FIG. 2, one feature of the first embodiment is that the back surface of the semiconductor chip CHP1 (reverse to the bump electrode bearing surface) is electrically coupled to the third-layer wiring L3, an internal wiring of the wiring board. In this case, if the third-layer wiring L3 functions as a reference wiring for supply of a reference voltage, the back surface of the semiconductor chip CHP1 (reverse to the bump electrode bearing surface) functions as a back electrode which supplies a reference voltage to the integrated circuit. Since the entire back surface of the semiconductor chip CHP1 can be used as a back electrode, the back electrode may be large enough to decrease the impedance. Therefore, even though the semiconductor chip CHP1 deals with high frequency signals, a reference voltage (GND) can be supplied stably without being affected by noise caused by high frequency signals. Concretely, a conductive film 11 is formed over the back surface of the semiconductor chip CHP1 (reverse to the bump electrode bearing surface) and this conductive film 11 functions as a back electrode which supplies a reference voltage to the integrated circuit. The conductive film 11 and third-layer wiring L3 are coupled through vias V as a plurality of holes filled with conductive material. More specifically, a plurality of openings are formed in the insulating layer 23 over the semiconductor chip CHP1 and these openings are filled with conductive material and serve as vias V to couple the conductive film 11 and the third-layer wiring L3. When the openings are completely filled with conductive material in this way, the electrical coupling between the conductive film 11 and the third-layer wiring L3 is more reliable than when only the side walls of the openings are coated with conductive material. Furthermore, when the openings are completely filled with conductive material, the contact resistance between the conductive film 11 and third-layer wiring L3 is decreased.

Another feature of the first embodiment is that the conductive film 11 is formed over the back surface of the semiconductor chip CHP1 and the conductive film 11 is electrically coupled to the third-layer wiring L3. It may be possible that the semiconductor chip CHP1 is directly electrically coupled to the third-layer wiring L3 without the conductive film 11 over the back surface of the chip. In that case, the semiconductor chip CHP1 contains silicon as a principal component and the third-layer wiring L3 is, for example, a copper film. Peeling might occur since adhesion between silicon and copper can not be so strong. If the semiconductor chip CHP1 should directly contact the third-layer wiring L3, peeling might occur between the semiconductor chip CHP1 (silicon) and the third-layer wiring L3 (copper film), causing an electrical coupling failure between the semiconductor chip CHP1 and the third-layer wiring L3.

For this reason, in the first embodiment, the conductive film 11 is formed over the back surface of the semiconductor chip CHP1 (reverse to the bump electrode bearing surface). The conductive film 11 is, for example, a copper film. If the conductive film 11 is a copper film, the strength of adhesion can be increased because the vias V and third-layer wiring L3 also use copper. In other words, in the first embodiment, the reliability of electrical coupling between the semiconductor chip CHP1 and third-layer wiring L3 is improved by forming the conductive film 11 over the back surface of the semiconductor chip CHP1 (reverse to the bump electrode bearing surface) and bringing the conductive film 11 and the third-layer wiring L3 into direct contact with each other through vias V. The material of the conductive film 11 is not limited to copper and it may be any material that provides a high strength of adhesion to the third-layer wiring L3. The conductive film 11 is for example, a coating but it may be a conductive sheet or conductive paste instead.

As described above, the first embodiment offers the following advantages. First, since the semiconductor chip CHP1 is embedded in the wiring board, the package size can be smaller. Second, since the semiconductor chip CHP1 embedded in the wiring board is flip-chip coupled to the base substrate 20 and wires are not used for electrical coupling between the semiconductor chip CHP1 and the wiring board, there is no possibility of signal delays and impedance rise due to high frequency signals passing through wires. Third, even though the semiconductor chip CHP1 is flip-chip coupled to the base substrate 20, a reference voltage (GND) is supplied stably without an influence of high frequency signal noise because the conductive film 11 formed over the back surface of the semiconductor chip CHP1 (reverse to the bump electrode bearing surface) is coupled to the third-layer wiring L3 through a plurality of vias V.

The features of the first embodiment have been so far described by taking the semiconductor chip CHP1 as an example. The same is true of the semiconductor chip CHP2 embedded in the wiring board. The semiconductor chip CHP1 is, for example, a power amplifier IC chip. Since such a power amplifier IC chip must supply a reference voltage stably, it is very useful to use the back surface of the semiconductor chip CHP1 (reverse to the bump electrode bearing surface) as a back electrode as in the first embodiment. Similarly, in case of the semiconductor chip CHP2 (for example, an RFIC chip), when it deals with signals in a frequency band of 5 GHz or more, supply of a reference voltage from the back side may be necessary. Therefore, it is very useful to use the back surface (reverse to the bump electrode bearing surface) of the semiconductor chip CHP2 flip-chip coupled (face down) as a back electrode. The semiconductor chip CHP3, which is mounted over the front surface of the wiring board, is, for example, a baseband IC chip. Although FIG. 2 shows that the semiconductor chip CHP3 is coupled face down over the front surface of the wiring board, it may be coupled by wires instead.

Next, the method of manufacturing the above-mentioned semiconductor device according to the first embodiment will be described referring to relevant drawings. First, a virtually disc shaped semiconductor wafer of monocrystal silicon is prepared. Then, an integrated circuit is formed over the main surface (first surface) of the semiconductor wafer. Specifically, a MISFET (Metal Insulator Semiconductor Field Effect Transistor) is formed over the main surface of the semiconductor wafer by carrying out an ordinary process for a substrate. Then, a multi-layer interconnection is made over the MISFET by carrying out an ordinary interconnection process. An integrated circuit is thus formed over the main surface of the semiconductor wafer.

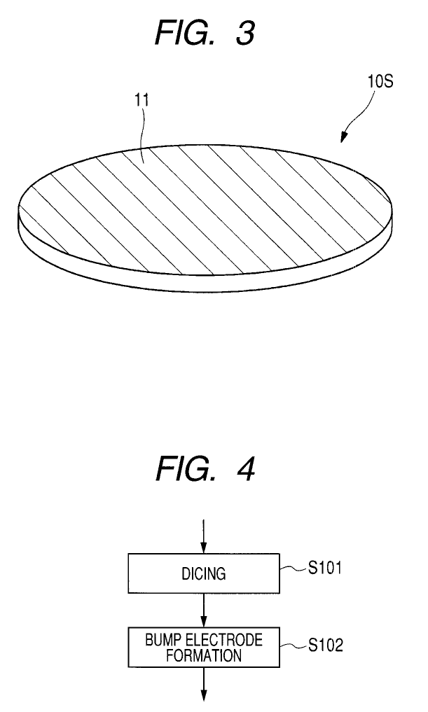

Next, as illustrated in FIG. 3, a conductive film 11 (hatched area in FIG. 3) is formed over the surface (second surface) reverse to the main surface of the semiconductor wafer 10S. This conductive film 11 is, for example, a copper film and formed by a coating method. The conductive film 11 is not limited to a copper film formed by coating but may be formed from a conductive sheet or conductive paste.

Next, as shown in FIG. 4, the semiconductor wafer is divided into semiconductor chips by dicing (S101). Bump electrodes are formed over individual semiconductor chips (S102). The bump electrodes are formed in the top layer of the main surface of each semiconductor chip.

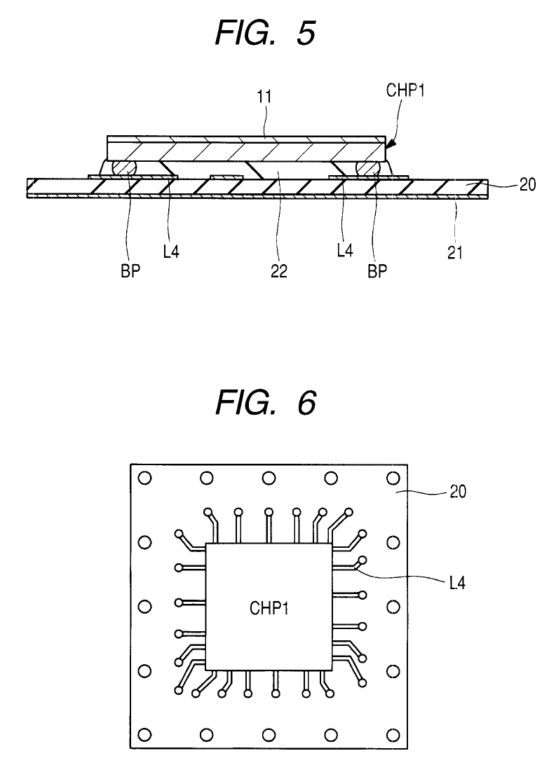

Next, as shown in FIG. 5, the semiconductor chip CHP1 is mounted over a base substrate 20. The base substrate 20 serves as the core layer of the wiring board and fourth-layer wiring L4 is formed over the front surface of the base substrate 20. On the other hand, a copper foil 21 is formed over the back surface of the base substrate 20. The semiconductor chip CHP1 is mounted over the front surface of the base substrate 20. Specifically it is mounted by coupling the bump electrodes BP of the semiconductor chip CHP1 to the fourth-layer wiring L4 formed over the base substrate 20. The space between the semiconductor chip CHP1 and the base substrate 20 is filled with paste 22. The semiconductor chip CHP1 is flip-chip coupled over the base substrate 20 in this way. The conductive film 11 lies over the back surface of the semiconductor chip CHP1 (reverse to the bump electrode bearing surface). FIG. 6 is a plan view showing what is shown in FIG. 5 (sectional view). As shown in FIG. 6, fourth-layer wiring L4 is formed over the rectangular base substrate 20 and the rectangular semiconductor chip CHP1 is mounted in the center area coupled to the fourth-layer wiring L4.

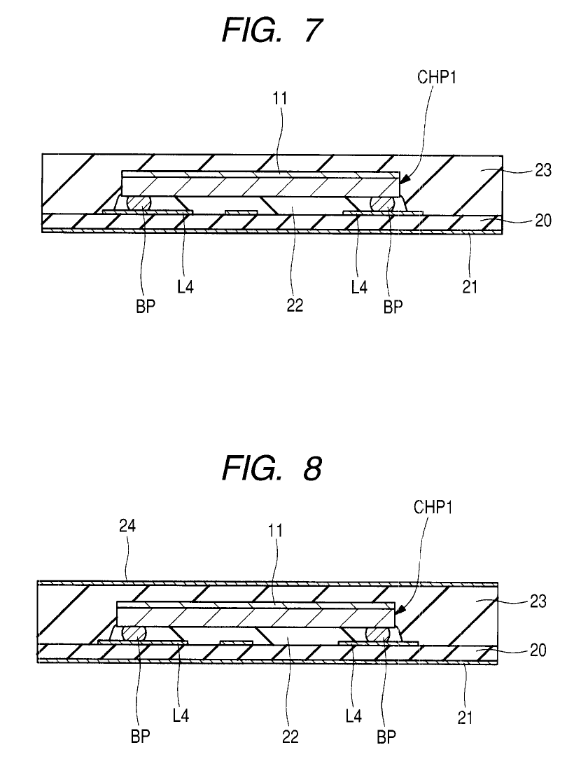

Next, as shown in FIG. 7, an insulating layer 23 is formed over the base substrate 20, over which the semiconductor chip CHP1 is mounted, in a way to cover the semiconductor chip CHP1. The insulating layer 23 is formed by making a thermosetting resin deposition (prepreg) and heating and pressing the resin. Then, as shown in FIG. 8, a copper foil 24 is formed over the insulating layer 23.

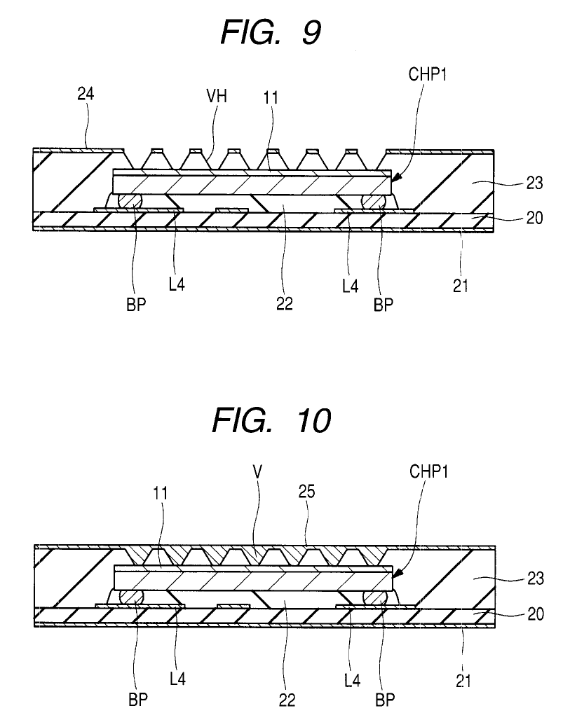

Next, a plurality of via holes (openings) VH are made in the insulating layer 23 as shown in FIG. 9. The via holes VH can be made by irradiating the insulating layer 23 with laser light. In the process of making via holes VH in the insulating layer 23, the copper foil 24 formed over the insulating layer 23 is patterned and irradiated with laser light to remove unwanted parts of the insulating layer 23. The via holes VH are formed so as to partially expose the conductive film 11 formed over the front surface of the semiconductor chip CHP1. Since the conductive film 11 is formed over the front surface of the semiconductor chip CHP1, it prevents laser light from chipping the silicon during laser light irradiation of the insulating layer 24 for formation of via holes VH. If there should be no conductive film 11 over the surface of the semiconductor chip CHP1, the laser light passing through the insulating layer 23 would reach the silicon. Contrariwise, in the first embodiment, since the conductive film 11 is formed over the front surface of the semiconductor chip CHP1, laser light is shielded by the conductive film 11. Therefore, one advantage is that laser light radiation does not cause silicon chipping in the process of making via holes VH in the insulating layer 23.

Next, a copper coating film 25 is made over the insulating layer 23 including the via holes VH made in it, as shown in FIG. 10. This copper coating film fills the via holes completely. These via holes VH are arranged evenly with respect to the semiconductor chip CHP1 so that the flatness of the copper coating film 25 which fills the via holes VH is improved. Vias V, namely via holes VH in which the copper coating film 25 is filled, are produced in this way. Since the vias V and the conductive film 11 formed over the front surface of the semiconductor chip CHP1 both use copper, the strength of adhesion between the conductive film 11 and vias V is increased.

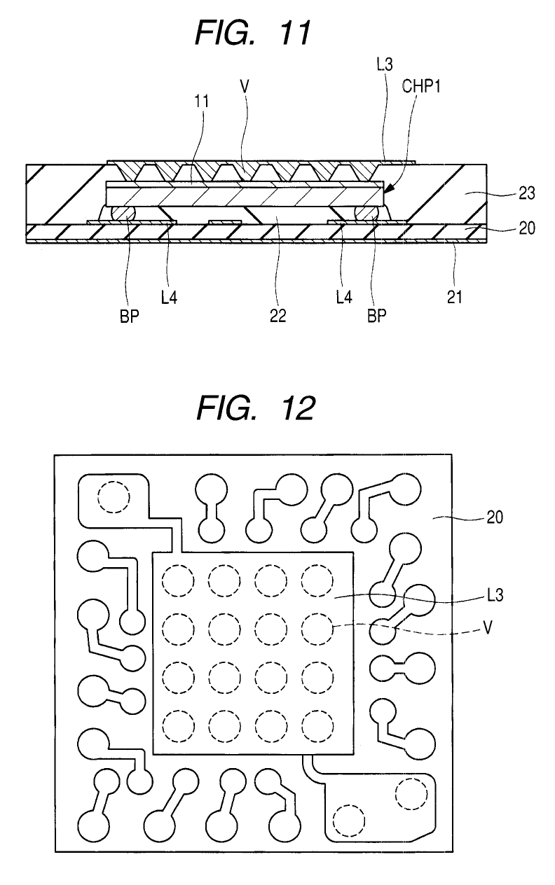

Next, third-layer wiring L3 is formed by patterning the copper coating film 25 formed over the insulating layer 23. Consequently the third-layer wiring L3 is electrically coupled to the conductive film 11 formed over the semiconductor chip CHP1 through a plurality of vias V. FIG. 12 is a plan view of what is shown in FIG. 11 (sectional view). As shown in FIG. 12, the third-layer wiring L3 lies over the base substrate 20 and vias V lie under the third-layer wiring L3. The vias V are evenly arranged throughout the region in which the third-layer wiring L3 is formed.

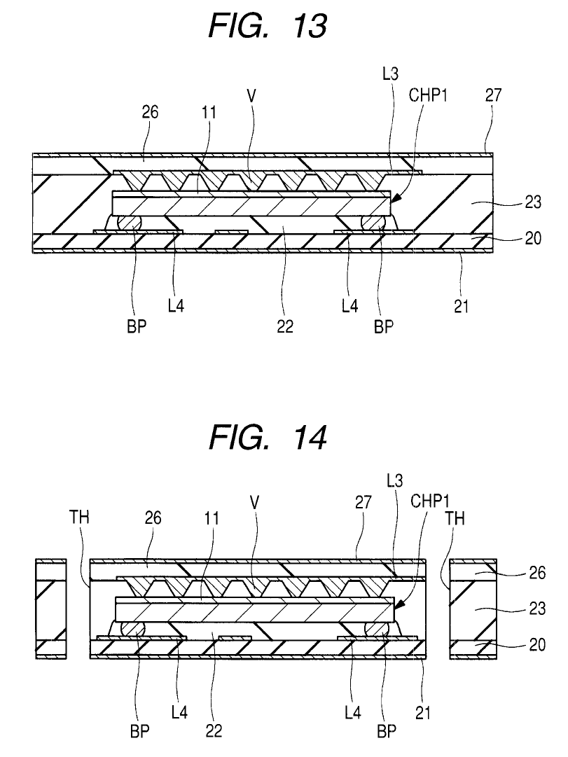

Next, as shown in FIG. 13, an insulating layer 26 is formed over the insulating layer 23 in which the third-layer wiring L3 is formed and a copper foil 27 is formed over the insulating layer 26. Then, as shown in FIG. 14, through holes TH which penetrate the wiring board are made as shown in FIG. 14.

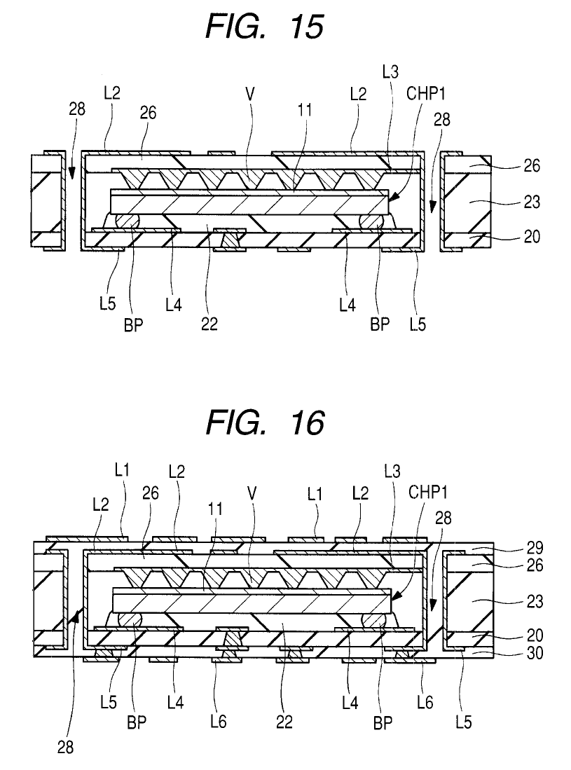

Then, as shown in FIG. 15, a copper coating film is formed over the wiring board including the inner walls of the through holes TH. Through wirings 28, as through holes TH whose inner walls are coated with copper, are made in this way. Then second-layer wiring L2 is made by pattering the copper foil 27 formed over the insulating layer 26. Furthermore, fifth-layer wiring L5 is made by patterning the copper foil 21 formed under the base substrate 20.

Next, an insulating layer 29 is formed over the insulating layer 26 including the second-layer wiring L2 as shown in FIG. 16. On the other hand, an insulating layer 30 is formed under the base substrate 20 including the fifth-layer wiring L5. The inside of each through wiring 28 is filled with the insulating layer 29 and insulating layer 30. Then, first-layer wiring L1 is made by pattering the copper foil formed over the insulating layer 29. Similarly, sixth-layer wiring L6 is made by pattering the copper foil formed under the insulating layer 30.

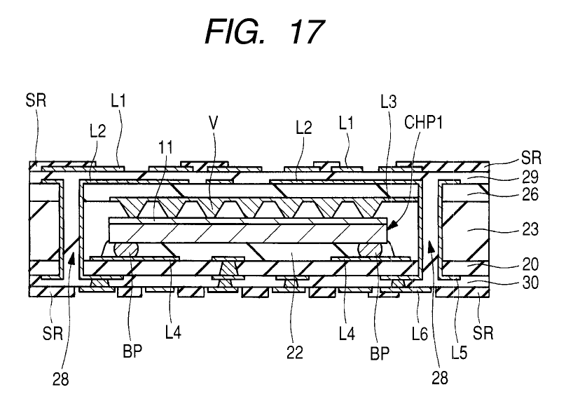

Then, solder resist SR is deposited over the first-layer wiring L1 as shown in FIG. 17 and patterning of the solder resist SR is done. The solder resist SR is patterned so as to open the semiconductor chip mounting region and passive component mounting region. Also, solder resist SR is deposited under the sixth-layer wiring L6 and patterning of the solder resist SR is done. The solder resist SR is patterned so as to open the solder ball mounting region.

Next, a semiconductor chip CHP3 and passive components 31 are mounted over the first-layer wiring L1 exposed from the solder resist SR as shown in FIG. 2. Then, solder balls HB are mounted under the sixth-layer wiring L6 exposed from the solder resist SR. The semiconductor device (package) according to the first embodiment is thus produced.

### Second Embodiment

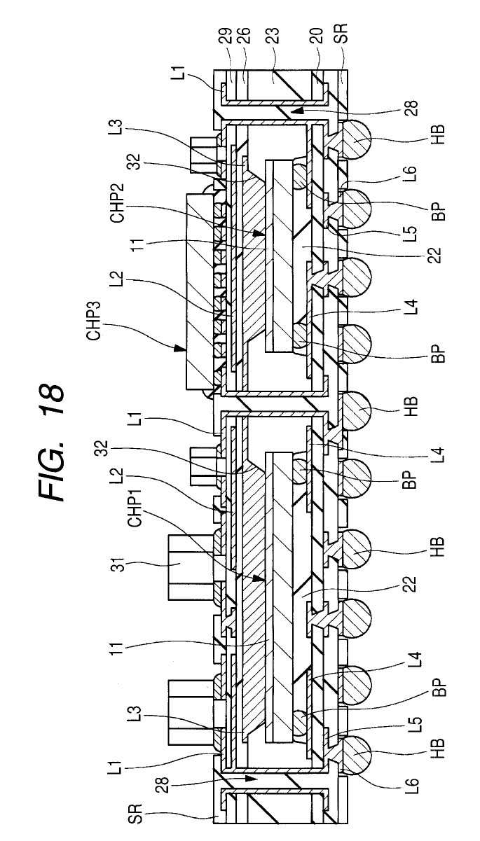

FIG. 18 is a sectional view of a package (semiconductor device) according to a second embodiment of the present invention. Since the structure of the package shown in FIG. 18 is almost the same as that of the package according to the first embodiment shown in FIG. 2, different points from the first embodiment are explained below.

Referring to FIG. 18, the second embodiment is characterized in the method of coupling between the conductive film 11 formed over the front surface of the semiconductor chip CHP1 and the third-layer wiring L3. Specifically, while the conductive film 11 is coupled to the third-layer wiring L3 through vias V (evenly arranged holes) in the first embodiment, the conductive film 11 and third-layer wiring L3 configure a large recessed area 32 in the second embodiment. This means that the area of contact between the conductive film 11 and the third-layer wiring L3 in the second embodiment is larger than in the first embodiment. Therefore, the contact resistance between the conductive film 11 and the third-layer wiring L3 can be low enough. Hence the impedance of the back electrode, comprised of the conductive film 11, can be low enough and a reference voltage (GND) can be stably supplied without an influence of noise due to high frequency signals.

In addition, since the area of contact between the conductive film 11 and the third-layer wiring L3 is large, the heat generated by the semiconductor chip CHP1 can be dissipated efficiently. Usually when the semiconductor chip CHP1 is embedded in the wiring board, the heat generated by the semiconductor chip CHP1 tends to dissipate hardly. In the second embodiment, heat is dissipated from the conductive film 11 formed over the entire front surface of the semiconductor chip CHP1 through the third-layer wiring L3, the package can provide a high heat dissipation efficiency even when the semiconductor chip CHP1 is embedded in the wiring board.

Since the rest of the second embodiment is the same as in the first embodiment, the second embodiment offers the same advantages as the first embodiment. Namely, it can ensure package size reduction and stable supply of a reference voltage and prevent deterioration in high frequency characteristics, leading to improvement of the semiconductor device quality.

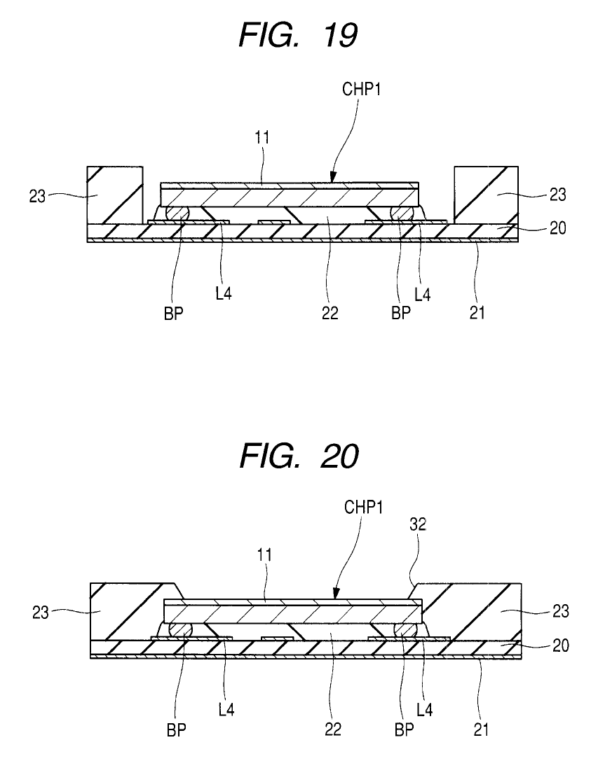

Next, the method of manufacturing the above-mentioned semiconductor device according to the second embodiment will be described referring to relevant drawings. The initial steps are the same as those shown in FIGS. 3 to 6 in the first embodiment. In the second embodiment, after those steps, an insulating layer 23 is formed over the base substrate 20 as shown in FIG. 19. The insulating layer 23 is located away from the semiconductor chip CHP1 formed over the base substrate 20. The insulating layer 23 is made of thermosetting resin and by heating and pressing the thermosetting resin, the insulating layer 23 of thermosetting resin, is formed over the base substrate 20 while a recessed area 32 containing no thermosetting resin is made over the semiconductor chip CHP1, as shown in FIG. 20. The recessed area 32 is thus formed as a large opening over the semiconductor chip CHP1. The size of the recessed area 32 is determined by adjusting the distance of the insulating layer (thermosetting resin) 23 from the semiconductor chip CHP1.

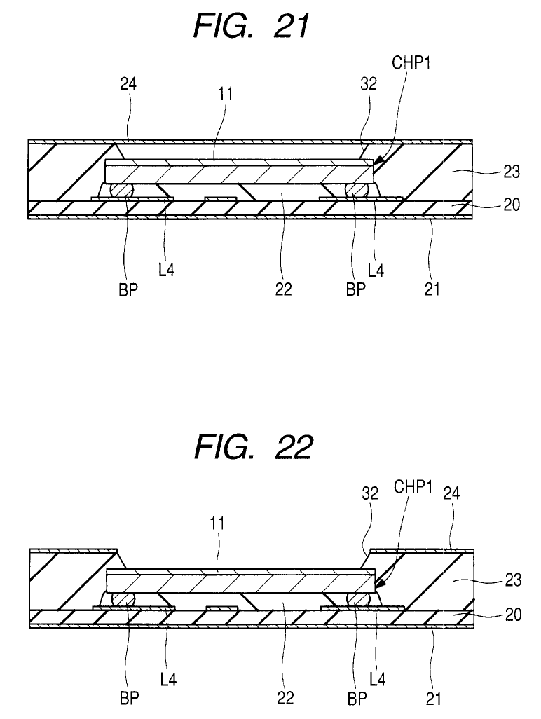

Next, as shown in FIG. 21, a copper foil 24 is formed over the insulating layer 23 including the recessed area 32 as shown in FIG. 21 and the copper foil 24 in the recessed area 32 is removed by patterning and etching as shown in FIG. 22.

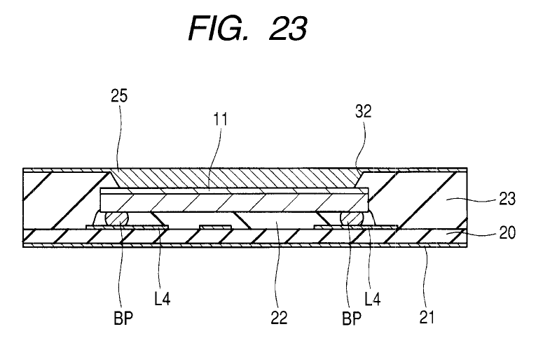

Then, as shown in FIG. 23, a copper coating film 25 is formed over the insulating layer 23 including the inside of the recessed area 32. The inside of the recessed area 32 is filled with the copper coating film 25. Consequently, the copper coating film 25 buried in the recessed area 32 is coupled to the conductive film 11 of the semiconductor chip CHP1 where the size of the contact area between them is the same as the size of the semiconductor chip CHP1. Since the conductive film 11 and the copper coating film 25 are made of the same material (for example, copper), the strength of adhesion between the conductive film 11 and the copper coating film 25 is increased.

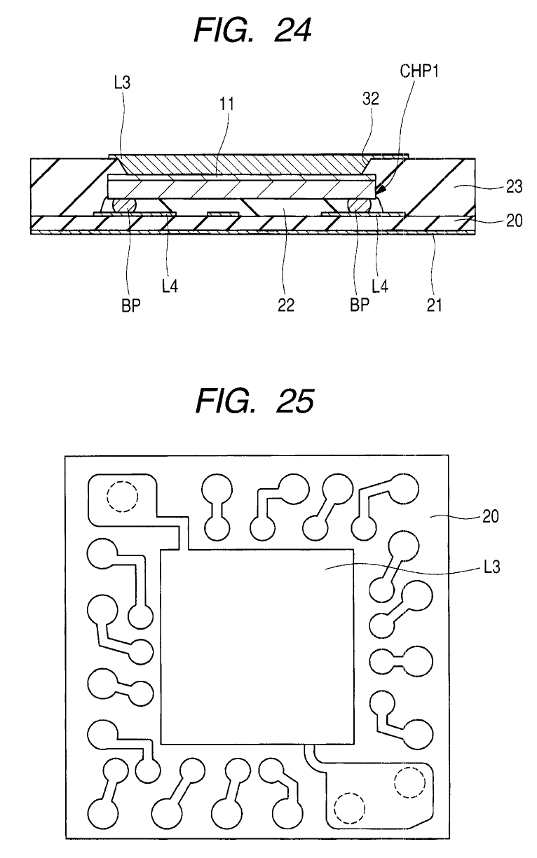

Next, third-layer wiring L3 is formed by patterning the copper coating film 25 formed over the insulating layer 23 as shown in FIG. 24. Consequently the third-layer wiring L3 is electrically coupled to the conductive film 11 of the semiconductor chip CHP1 through the recessed area 32. FIG. 25 is a plan view of what is shown in FIG. 24 (sectional view). As shown in FIG. 25, the rectangular third-layer wiring L3, which has almost the same size as the semiconductor chip CHP1, is formed over the base substrate 20 and the recessed area 32 (not shown) is formed under the third-layer wiring L3.

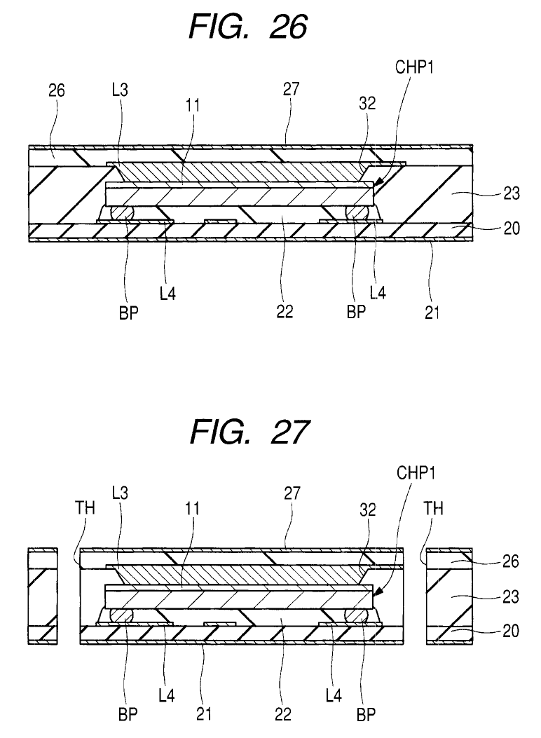

Then, as shown in FIG. 26, an insulating layer 26 is formed over the insulating layer 23 in which the third-layer wiring L3 is formed and a copper foil 27 is formed over the insulating layer 26. Then, through holes TH which penetrate the wiring board are made as shown in FIG. 27.

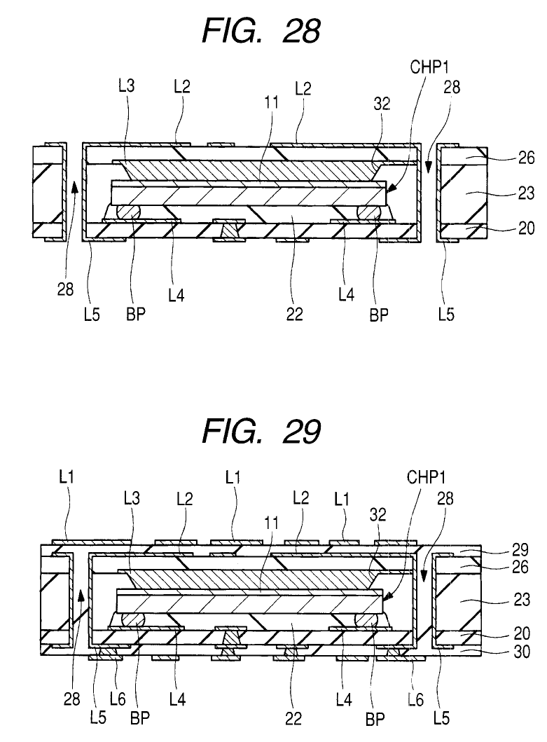

Then, as shown in FIG. 28, a copper coating film is formed over the wiring board including the inner walls of the through holes TH. Through wirings 28, in the form of through holes TH whose inner walls are coated with copper, are made in this way. Then second-layer wiring L2 is made by pattering the copper foil 27 made over the insulating layer 26. Furthermore, fifth-layer wiring L5 is made by patterning the copper foil 21 formed under the base substrate 20.

Next, an insulating layer 29 is formed over the insulating layer 26 including the second-layer wiring L2 as shown in FIG. 29. On the other hand, an insulating layer 30 is formed under the base substrate 20 including the fifth-layer wiring L5. The insides of the through wirings 28 are filled with the insulating layer 29 and insulating layer 30. Then, first-layer wiring L1 is made by pattering the copper foil formed over the insulating layer 29. Similarly, sixth-layer wiring L6 is made by pattering the copper foil formed under the insulating layer 30.

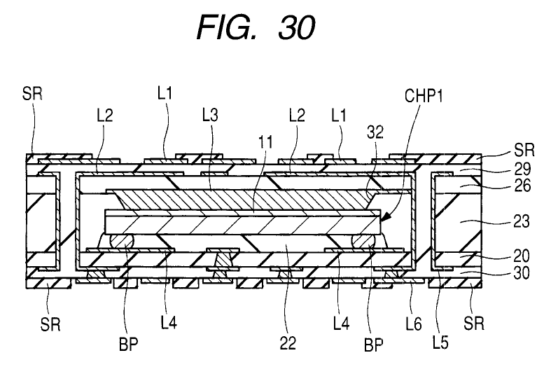

Then, solder resist SR is deposited over the first-layer wiring L1 as shown in FIG. 30 and patterning of the solder resist SR is done. The solder resist SR is patterned so as to open the semiconductor mounting region and passive component mounting region. Also, solder resist SR is deposited under the sixth-layer wiring L6 and patterning of the solder resist SR is done. The solder resist SR is patterned so as to open the solder ball mounting region.

Next, a semiconductor chip CHP3 and passive components 31 are mounted over the first-layer wiring L1 exposed from the solder resist SR as shown in FIG. 18. Then, solder balls HB are mounted under the sixth-layer wiring L6 exposed from the solder resist SR. The semiconductor device (package) according to the second embodiment is thus produced.

### Third Embodiment

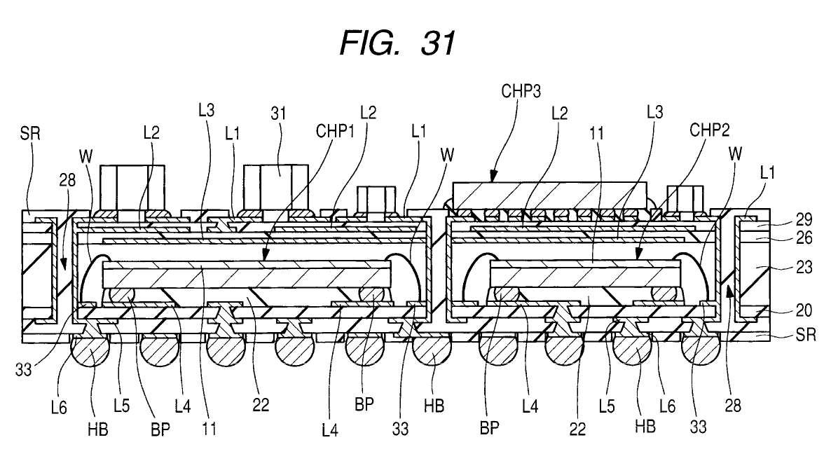

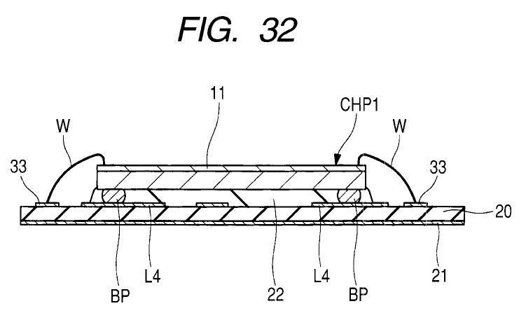

FIG. 31 is a sectional view of a package (semiconductor device) according to a third embodiment of the present invention. Since the structure of the package shown in FIG. 31 is almost the same as that of the package according to the first embodiment shown in FIG. 2, different points from the first embodiment are explained below.

Referring to FIG. 31, the third embodiment is characterized in the method of coupling between the conductive film 11 formed over the front surface of the semiconductor chip CHP1 and the reference wiring. Specifically, while the conductive film 11 is coupled to the third-layer wiring L3 through vias V (evenly arranged holes) in the first embodiment, the conductive film 11 is not coupled to the third-layer wiring L3 but the conductive film 11 is coupled to wiring 33 made in the same layer as the fourth-layer wiring L4 by wires W. Therefore, according to the third embodiment, wiring to the conductive film 11 can be made freely by wires W and wiring work for the wiring board is simplified.

As shown in FIG. 31, wires W are used to couple the conductive film 11 to the wiring 33 which supplies a reference voltage. Since the wires W do not transmit high frequency signals but supply a reference voltage through the conductive film 11 to the semiconductor chip CHP1, delays in high frequency signals do not occur in spite of the use of the wires W.

Since the rest of the third embodiment is the same as in the first embodiment, the third embodiment offers the same advantages as the first embodiment. Namely, it can ensure package size reduction and stable supply of a reference voltage and prevent deterioration in high frequency characteristics, leading to improvement of the semiconductor device quality.

Next, the method of manufacturing the above-mentioned semiconductor device according to the third embodiment will be described referring to relevant drawings. The initial steps are the same as those shown in FIGS. 3 to 6 in the first embodiment. In the third embodiment, after those steps, the conductive film formed over the semiconductor chip CHP1 is coupled to the wiring 33 formed over the base substrate 20 by wires W. These wires W are reference wires which transmit the reference voltage. The wire bonding accuracy required to couple wires W to the conductive film 11 is not so high. In other words, while high positioning accuracy in wire bonding is required to couple pads and wirings by wires because of the smallness of the pads, the required positioning accuracy in wire bonding is not so high in the third embodiment because it is enough to couple wires to any part of the conductive film 11 which lies all over the semiconductor chip CHP1.

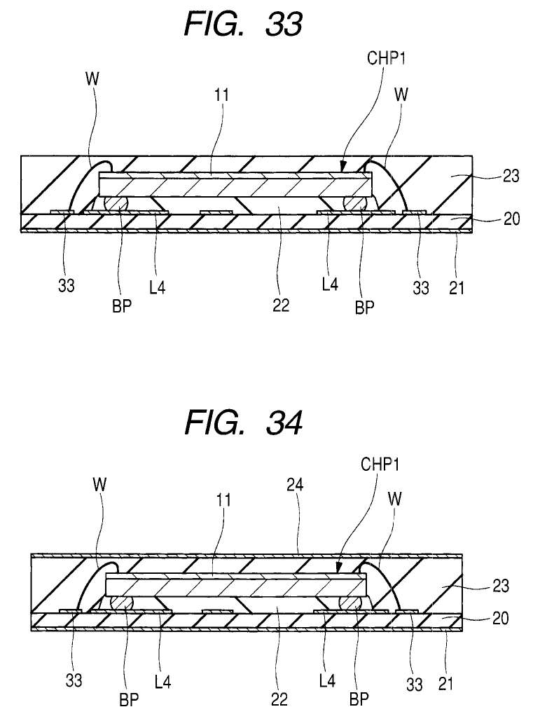

Next, as shown in FIG. 33, an insulating layer 23 is formed over the base substrate 20, over which the semiconductor chip CHP1 is mounted, in a way to cover the semiconductor chip CHP1. The insulating layer 23 is formed by making a thermosetting resin deposition (prepreg) over the base substrate 20 and heating and pressing the resin. Consequently the wires W are also fixed by the insulating layer 23. Then, as shown in FIG. 34, a copper foil 24 is formed over the insulating layer 23.

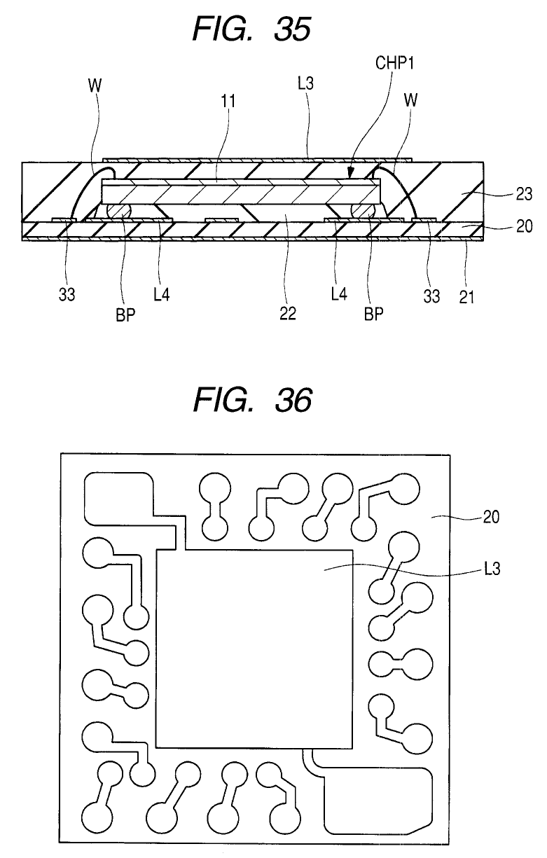

Next, third-layer wiring L3 is formed by patterning the copper foil 24 formed over the insulating layer 23 as shown in FIG. 35. FIG. 36 is a plan view of what is shown in FIG. 35 (sectional view). As shown in FIG. 36, the rectangular third-layer wiring L3, which has almost the same size as the semiconductor chip CHP1, is formed over the base substrate 20 and wires W (not shown) is formed under the third-layer wiring L3.

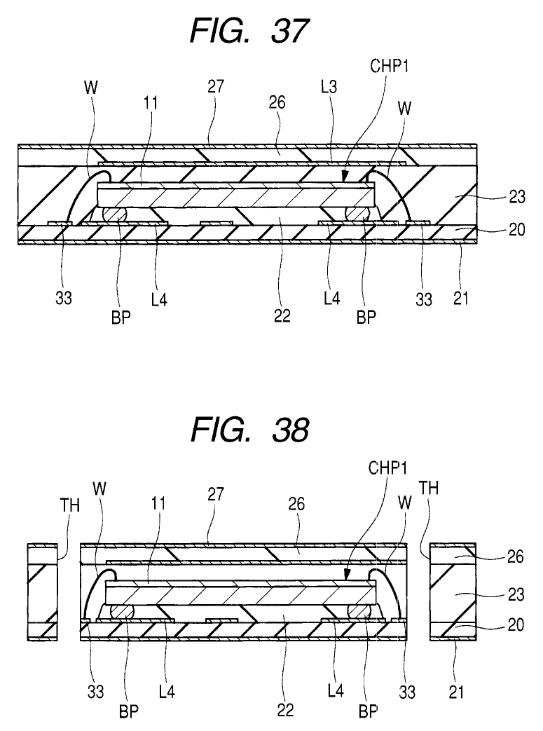

Then, as shown in FIG. 37, an insulating layer 26 is formed over the insulating layer 23 in which the third-layer wiring L3 is formed and a copper foil 27 is formed over the insulating layer 26. Then, through holes TH which penetrate the wiring board are made as shown in FIG. 38.

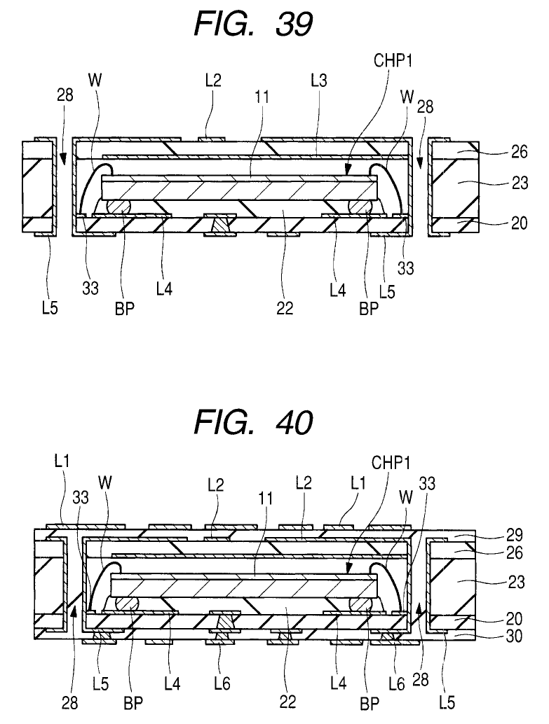

Then, as shown in FIG. 39, a copper coating film is formed over the wiring board including the inner walls of the through holes TH. Through wirings 28, in the form of through holes TH whose inner walls are coated with copper, are made in this way. Then second-layer wiring L2 is made by pattering the copper foil 27 formed over the insulating layer 26. Furthermore, fifth-layer wiring L5 is made by patterning the copper foil 21 formed under the base substrate 20.

Next, an insulating layer 29 is formed over the insulating layer 26 including the second-layer wiring L2 as shown in FIG. 40. On the other hand, an insulating layer 30 is formed under the base substrate 20 including the fifth-layer wiring L5. The insides of the through wirings 28 are filled with the insulating layer 29 and insulating layer 30. Then, first-layer wiring L1 is made by pattering the copper foil formed over the insulating layer 29. Similarly, sixth-layer wiring L6 is made by pattering the copper foil formed under the-insulating layer 30.

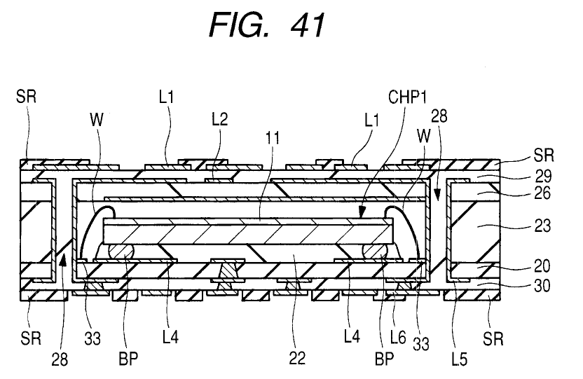

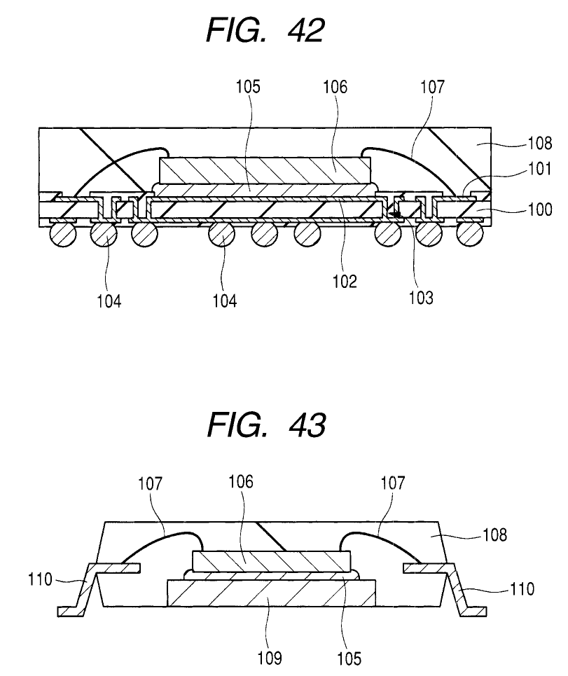

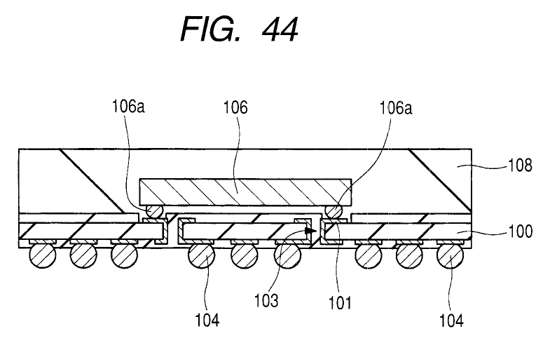

Then, solder resist SR is deposited over the first-layer wiring L1 as shown in FIG. 41 and patterning of the solder resist SR is done. The solder resist SR is patterned so as to open the semiconductor mounting region and passive component mounting region. Also, solder resist SR is deposited under the sixth-layer wiring L6 and patterning of the solder resist SR is done. The solder resist SR is patterned so as to open the solder ball mounting region.

Next, a semiconductor chip CHP3 and passive components 31 are mounted over the first-layer wiring L1 exposed from the solder resist SR as shown in FIG. 31. Then, solder balls HB are mounted under the sixth-layer wiring L6 exposed from the solder resist SR. The semiconductor device (package) according to the third embodiment is thus produced.

The invention made by the present inventors has been so far concretely described in reference to preferred embodiments thereof. However, the present invention is not limited to the embodiments and it is obvious that the invention may be modified in various ways without departing from the spirit and scope thereof.

The invention can be widely used in the semiconductor device manufacturing industry.

What is claimed is:

1. A semiconductor device comprising:
(a) a rectangular first semiconductor chip; and
(b) a wiring board in which the first semiconductor chip is embedded,
the first semiconductor chip comprising:
(a1) bump electrodes formed over a first surface of the first semiconductor chip;
(a2) a conductive film formed over a second surface opposing to the first surface of the first semiconductor chip, the conductive film being a back electrode, the wiring board comprising:
(b1) a core layer coupled to the first semiconductor chip through the bump electrodes formed over the first surface of the first semiconductor chip;
(b2) an insulating layer formed over a chip-mounting surface of the core layer such that the first semiconductor chip is covered with the insulating layer;
(b3) an opening reaching from the insulating layer to the conductive film formed over the second surface of the first semiconductor chip;
(b4) a conductive via filling the opening; and
(b5) wiring coupled to the via,
wherein the conductive film formed over the second surface of the first semiconductor chip is electrically coupled to the wiring formed in the wiring board through the via.

2. The semiconductor device according to claim 1, wherein the opening is a recessed area.

3. The semiconductor device according to claim 1, wherein the opening includes a plurality of holes.

4. The semiconductor device according to claim 1, wherein the wiring is an internal wiring formed inside the wiring board.

5. The semiconductor device according to claim 1, wherein the via is filled with a conductive material.

6. The semiconductor device according to claim 1, wherein the conductive film functions as the back electrode which supplies a reference voltage to an integrated circuit formed inside the first semiconductor chip.

7. The semiconductor device according to claim 6, wherein the wiring electrically coupled to the conductive film is a reference wiring which supplies a reference voltage.

8. The semiconductor device according to claim 1, wherein a plurality of the first semiconductor chips are embedded in the wiring board.

9. The semiconductor device according to claim 8, wherein a second semiconductor chip different from the first semiconductor chip and a passive component are mounted over the wiring board's front surface.

10. The semiconductor device according to claim 9,
wherein the first semiconductor chip embedded in the wiring board includes a plurality of IC chips having a mobile phone function to transmit and receive signals, and
wherein the IC chips are an RFIC chip having a function to modulate a baseband signal into a radio frequency signal in transmission and demodulate a radio frequency signal into a baseband signal in reception and a power amplifier IC chip having a function to amplify electric power of a radio frequency signal generated by the RFIC chip in transmission.

11. The semiconductor device according to claim 10, wherein the second semiconductor chip mounted over the wiring board's front surface is a baseband IC chip which processes baseband signals.

12. The semiconductor device according to claim 1, wherein the first semiconductor chip includes silicon as a principal component,
wherein the conductive film formed over the second surface of the first semiconductor chip is a copper film, and
wherein the conductive material filled in the via and the wiring coupled to the conductive film through the via are copper film.

13. A semiconductor device comprising:
(a) a rectangular semiconductor chip; and
(b) a wiring board in which the semiconductor chip is embedded,
the semiconductor chip comprising:
(a1) bump electrodes formed over a first surface of the semiconductor chip; and
(a2) a conductive film formed over a second surface opposing to the first surface of the semiconductor chip, the conductive film being a back electrode,
the wiring board comprising:
(b1) a core layer coupled to the semiconductor chip through the bump electrodes formed over the first surface of the semiconductor chip;
(b2) wiring formed in the core layer; and
(b3) an insulating layer formed over a chip-mounting surface of the core layer such that the semiconductor chip is covered with the insulating layer,
wherein the conductive film formed over the second surface of the semiconductor chip is coupled to the wiring formed in the core layer through wires; and
wherein the wires are fixed by the insulating layer.

14. A method of manufacturing a semiconductor device comprising the steps of:
(a) forming an integrated circuit over a first surface of a semiconductor wafer;
(b) after the step (a), forming a first conductive film over a second surface opposing to the first surface of the semiconductor wafer;
(c) after the step (b), dicing the semiconductor wafer into separate semiconductor chips;
(d) after the step (c), forming bump electrodes over the first surface of the semiconductor chip;
(e) after the step (d), mounting the semiconductor chip over a base substrate through the bump electrodes, wherein the base substrate is a core layer of a wiring board;
(f) after the step (e), forming an insulating layer over a chip-mounting surface of the base substrate, the insulating layer covering the semiconductor chip;
(g) after the step (f), making an opening reaching from the insulating layer to the first conductive film formed over the second surface of the semiconductor chip;
(h) after the step (g), forming a via by filling a second conductive film in the opening by forming the second conductive film over the insulating layer including the opening; and
(i) after the step (h), forming a wiring by patterning the second conductive film formed over the insulating layer and the via,
wherein the first conductive film formed over the second surface of the semiconductor chip and the wiring formed over the insulating layer are electrically coupled through the via to each other.

15. The method of manufacturing a semiconductor device according to claim 14, wherein at the step (g) the opening is made by irradiating the insulating layer with laser light.

16. The method of manufacturing a semiconductor device according to claim 14, wherein the first conductive film formed at the step (b) is a coating film.

17. The method of manufacturing a semiconductor device according to claim 14, wherein the first conductive film formed at the step (b) is a conductive sheet or conductive paste.

18. A method of manufacturing a semiconductor device comprising the steps of:
(a) forming an integrated circuit over a first surface of a semiconductor wafer;
(b) after the step (a), forming a first conductive film over a second surface opposing to the first surface of the semiconductor wafer;
(c) after the step (b), dicing the semiconductor wafer into separate semiconductor chips;
(d) after the step (c), forming bump electrodes over the first surface of the semiconductor chip;
(e) after the step (d), mounting the semiconductor chip over a base substrate through the bump electrodes, wherein the base substrate is a core layer of a wiring board;
(f) after the step (e), forming an insulating layer over a chip-mounting surface of the base substrate, so as to make a recessed area in the second surface of the semiconductor chip;
(g) after the step (f), forming a via by filling a second conductive film in the recessed area by forming the second conductive film over the insulating layer including the inside of the recessed area; and
(h) after the step (g), forming a wiring by patterning the second conductive film formed over the insulating layer and the via,
wherein the first conductive film formed over the second surface of the semiconductor chip and the wiring formed over the insulating layer are electrically coupled through the via to each other.

19. The method of manufacturing a semiconductor device according to claim 18, wherein at the step (f), a thermosetting resin deposition is made over the base substrate away from the semiconductor chip formed over the base substrate and an insulating layer of the thermosetting resin is formed by heating and pressing the thermosetting resin while making, over the semiconductor chip, a recessed area having no thermosetting resin.

20. A method of manufacturing a semiconductor device comprising the steps of:
(a) forming an integrated circuit over a first surface of a semiconductor wafer;
(b) after the step (a), forming a first conductive film over a second surface opposing to the first surface of the semiconductor wafer;
(c) after the step (b), dicing the semiconductor wafer into separate semiconductor chips;
(d) after the step (c), forming bump electrodes over the first surface of the semiconductor chip;
(e) after the step (d), mounting the semiconductor chip over a base substrate through the bump electrodes, wherein the base substrate is a core layer of a wiring board;
(f) after the step (e), coupling a wiring formed over the base substrate to the first conductive film formed over the second surface of the semiconductor chip by wires; and
(g) after the step (f), forming an insulating layer over a chip-mounting surface of the base substrate, the insulating layer covering the semiconductor chip and the wires.
